(19) United States
(12) Patent Application Publication
(10) Pub. No.: US 2026/0136531 A1
(43) Pub. Date: May 14, 2026

(54) MEMORY CELL, MEMORY AND MANUFACTURING METHOD THEREOF, AND ELECTRONIC EQUIPMENT

(71) Applicant: BEIJING SUPERSTRING ACADEMY OF MEMORY TECHNOLOGY, Daxing District, Beijing (CN)

(72) Inventors: Shujuan MAO, Beijing (CN); Chao ZHAO, Beijing (CN); Guilei WANG, Beijing (CN); Yuke LI, Beijing (CN)

(73) Assignee: BEIJING SUPERSTRING ACADEMY OF MEMORY TECHNOLOGY, Daxing District, Beijing (CN)

(21) Appl. No.: 18/705,169

(22) PCT Filed: Oct. 11, 2023
(86) PCT No.: PCT/CN2023/124025

§ 371 Date: Apr. 26, 2024

(30) Foreign Application Priority Data
Jun. 27, 2023 (CN) 202310767383.4

(51) Int. Cl. H10B 12/00

(52) U.S. Cl. CPC H10B 12/315; H10B 12/05

(57) ABSTRACT

Provided is a memory cell. A vertical transistor of the memory cell includes a semiconductor pillar including a drain region, a channel region, and a source region disposed sequentially; and a gate insulating layer and a gate, the gate and at least a portion of the gate insulating layer being disposed sequentially around the channel region of the semiconductor pillar; wherein the vertical transistor includes at least one of: the gate insulating layer proximal to the source region having a greater dielectric constant than the gate insulating layer proximal to the drain region, or, the gate proximal to the source region having a greater work function than the gate proximal to the drain region; and the drain region is configured to be electrically connected to a bitline, and the source region is configured to be electrically connected to a capacitor structure.

### RELATED APPLICATION DATA

This application is a U.S. national stage of International Application No. PCT/CN 2023/124025, filed on Oct. 11, 2023, which claims priority to Chinese Patent Application No. 202310767383.4, filed on Jun. 27, 2023, and entitled “MEMORY CELL, MEMORY AND MANUFACTURING METHOD THEREOF, AND ELECTRONIC EQUIPMENT”, the contents of which are incorporated herein by reference in their entireties.

### TECHNICAL FIELD

The present disclosure relates to the technical field of semiconductors, in particular, relates to a memory cell, a memory and a method for manufacturing the same.

### BACKGROUND

Memory technology is currently advancing to increase integration and reduce element size. In order to improve the integration capability and reduce the cell area, more memory cells are required to be formed in a chip with a certain area, and the size of a memory device is desired to be scaled down continuously as the technology advances.

### SUMMARY

The present disclosure provides a memory cell, a memory and a method for manufacturing the same.

Embodiments of the present disclosure provide a memory cell. The memory cell includes a vertical transistor, the vertical transistor including:
a semiconductor pillar extending in a direction perpendicular to a substrate and including a drain region, a channel region, and a source region disposed sequentially; and
a gate insulating layer and a gate, the gate and at least a portion of the gate insulating layer being disposed sequentially around the channel region of the semiconductor pillar;
wherein the gate insulating layer proximal to the source region has a greater dielectric constant than the gate insulating layer proximal to the drain region; and/or, the gate proximal to the source region has a greater work function than the gate proximal to the drain region; and the drain region is configured to be electrically connected to a bitline, and the source region is configured to be electrically connected to a capacitor structure.

Embodiments of the present disclosure provide a memory. The memory includes: a plurality of wordlines, and memory cells as defined in the embodiments and arranged in an array;

each of the wordlines is electrically connected to the gates of the memory cells arranged in a same row in a first direction, the first direction being parallel to the substrate.

Embodiments of the present disclosure provide a method for manufacturing a memory. The method for manufacturing a memory includes:
forming, at a side of a substrate, semiconductor pillars arranged in an array and extending in a direction perpendicular to the substrate, each of the semiconductor pillars including a drain region, a channel region, and a source region disposed sequentially;
forming a plurality of gates and a plurality of wordlines such that the gates and the wordlines are disposed sequentially around the channel regions of the semiconductor pillars and the gates are insulated from the semiconductor pillars; and
forming a plurality of gate insulating layers such that at least a portion of each of the gate insulating layers is disposed around the channel region of the semiconductor pillar and disposed between the semiconductor pillar and the gate, the gate insulating layer proximal to the source region having a greater dielectric constant than the gate insulating layer proximal to the drain region; and/or, the gate proximal to the source region having a greater work function than the gate proximal to the drain region; and the drain region being configured to be electrically connected to a bitline, and the source region being configured to be electrically connected to a capacitor structure.

### BRIEF DESCRIPTION OF THE DRAWINGS

FIG. 1 is a schematic cross-sectional view of a first vertical transistor according to some embodiments of the present disclosure;

FIG. 2 is a schematic cross-sectional view of a second vertical transistor according to some embodiments of the present disclosure;

FIG. 3 is a schematic cross-sectional view of a third vertical transistor according to some embodiments of the present disclosure;

FIG. 4 is a schematic top view of a memory according to some embodiments of the present disclosure;

FIG. 5 is a schematic cross-sectional view of the first memory in a first direction according to some embodiments of the present disclosure;

FIG. 6 is a schematic cross-sectional view of the first memory in a second direction according to some embodiments of the present disclosure;

FIG. 7 is a schematic cross-sectional view of the second memory in the first direction according to some embodiments of the present disclosure;

FIG. 8 is a schematic cross-sectional view of the second memory in the second direction according to some embodiments of the present disclosure;

FIG. 9 is a schematic cross-sectional view of the third memory in the first direction according to some embodiments of the present disclosure;

FIG. 10 is a schematic cross-sectional view of the third memory in the second direction according to some embodiments of the present disclosure;

FIG. 11 is a flowchart illustrating a method for manufacturing any one of the memories according to some embodiments of the present disclosure;

FIG. 12 to FIG. 27 are schematic views obtained from steps in the flowchart illustrating the method for manufacturing any one of the memories according to some embodiments of the present disclosure;

FIG. 28 to FIG. 43 are schematic views obtained from steps in a flowchart illustrating a method for manufacturing the first memory according to some embodiments of the present disclosure; and FIG. 44 to FIG. 59 are schematic views obtained from steps in a flowchart illustrating a method for manufacturing the second memory according to some embodiments of the present disclosure.

### DETAILED DESCRIPTION

Embodiments of the present disclosure are described below in conjunction with the accompanying drawings in the present disclosure. It should be understood that the embodiments set forth below in conjunction with the accompanying drawings are exemplary descriptions for explaining technical solutions of the embodiments of the present disclosure, and do not limit the technical solutions of the embodiments of the present disclosure.

As will be understood by those skilled in the art, the singular forms “a”, “an”, “one”, and “the”, as used herein, are intended to include plural forms as well, unless specifically stated otherwise. It should be further understood that the term “include”, as used herein, refers to the presence of stated features, integers, steps, operations, elements, and/or components, but does not exclude the implementation of other features, information, data, steps, operations, elements, components, and/or combinations thereof, as supported in the art. The term “and/or” as used herein refers to at least one of the items defined by the term, e.g., “A and/or B” may be implemented as “A”, or “B”, or “A and B”.

For clearer descriptions of the objects, technical solutions, and advantages of the present disclosure, embodiments of the present disclosure are further described in detail below with reference to the accompanying drawings.

The idea of the present disclosure is illustrated as follows. The 4F² dynamic random access memory (DRAM) technology, which combines a vertical transistor with a capacitor structure, is the main development direction of DRAM in the future. However, the current DRAM has a problem of large leakage, which is likely to cause deterioration in charge retention time.

Specifically, the floating body effect generated by the vertical transistor in the memory is likely to form a parasitic triode, which causes the problem of leakage, such that the charge retention time is deteriorated.

The following describes the technical solutions of the present disclosure and how the technical solutions solve the technical problem described above in detail with specific embodiments. It should be noted that the following embodiments may refer to or combine with each other, and the like terms, similar features, and similar implementation steps in different embodiments are not repeated herein.

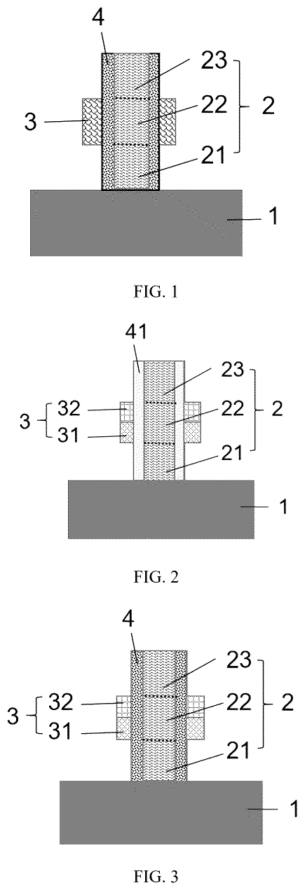

The embodiments of the present disclosure provide a memory cell. The memory cell includes a vertical transistor. The vertical transistor has a structure schematically shown in FIG. 1 to FIG. 3, and includes a semiconductor pillar 2, a gate insulating layer 4, and a gate 3.

The semiconductor pillar 2 extends in a direction perpendicular to a substrate 1 and includes a drain region 21, a channel region 22, and a source region 23 disposed sequentially.

The gate 3 and at least a portion of the gate insulating layer 4 are disposed sequentially around the channel region 22 of the semiconductor pillar 2.

The gate insulating layer 4 proximal to the source region 23 has a greater dielectric constant than the gate insulating layer 4 proximal to the drain region 21; and/or, the gate 3 proximal to the source region 23 has a greater work function than the gate 3 proximal to the drain region 21. The drain region 21 is configured to be electrically connected to a bitline 6, and the source region 23 is configured to be electrically connected to a capacitor structure 71.

It should be understood that the semiconductor pillar 2 includes the drain region 21, the channel region 22, and the source region 23 disposed sequentially. The drain region 21 or the source region 23 is disposed at a side of the channel region 22 proximal to the substrate 1. In general, the source region 23 is electrically connected to the capacitor structure 71, so the present disclosure is specifically described with the drain region 21 being disposed at the side of the channel region 22 proximal to the substrate 1, and the source region 23 being disposed at a side of the channel region 22 distal to the substrate 1, for example.

In the embodiments, FIG. 1 is a schematic view of the first vertical transistor according to some embodiments of the present disclosure. In FIG. 1, the gate 3 has a consistent work function, while the gate insulating layer 4 has a gradient dielectric constant value. Specifically, the gate insulating layer 4 proximal to the source region 23 has a greater dielectric constant than the gate insulating layer 4 proximal to the drain region 21. With a great dielectric constant of the gate insulating layer 4 proximal to the source region 23, the coupling between the gate 3 and the source is enhanced, which is conducive to increasing the band barrier height of the source region 23 and the channel region 22. With a small dielectric constant of the gate insulating layer 4 proximal to the drain region 21, the electric field between the drain region 21 and the channel region 22 is reduced, which is conducive to increasing the band barrier width of the drain region 21 and the channel region 22. Therefore, the gate insulating layer 4 having the gradient dielectric constant value suppresses the turn-on of the parasitic triode, thereby reducing the induced leakage.

FIG. 2 is a schematic view of the second vertical transistor according to some embodiments of the present disclosure. In FIG. 2, the gate insulating layer 41 has a constant dielectric constant value, while the gate 3 has different work functions. Specifically, the gate 3 proximal to the source region 23 has a greater work function than the gate 3 proximal to the drain region 21. With a great work function of the gate 3 proximal to the source region 23 and a small work function of the gate 3 proximal to the drain region 21, the electric field distribution in the channel region 22 becomes more uniform, such that an on-state current is increased, and meanwhile, the transverse band-band tunneling width is increased, which is conducive to reducing the off-state leakage current, thereby improving the on-off ratio of the memory.

FIG. 3 is a schematic view of the third vertical transistor according to some embodiments of the present disclosure. In FIG. 3, the gate insulating layer 4 has a gradient dielectric constant value, and the gate 3 has different work functions. The gate insulating layer 4 having the gradient dielectric constant value suppresses the turn-on of the parasitic triode, thereby reducing the leakage. The gate 3 having different work functions enables the electric field distribution in the channel region 22 to be more uniform, such that an on-state current is increased, and meanwhile, the transverse band-band tunneling width is increased, which is conducive to reducing the off-state leakage current, thereby improving the on-off ratio of the memory.

It should be noted that a material of the semiconductor pillar 2 is silicon or silicon germanium.

In some embodiments, the electric field distribution in the channel region 22 is uniform.

In the embodiments, the uniformity of the electric field distribution in the channel region 22 increases the on-state current.

In some embodiments, the gate insulating layer 4 proximal to the drain region 21 has a dielectric constant greater than 1 and no more than 3.9, and the gate insulating layer 4 proximal to the source region 23 has a dielectric constant greater than 3.9 and no more than 50.

In the embodiments, the dielectric constant of the gate insulating layer 4 is within the range described above, which reduces the electric field between the channel and the drain and enhances the coupling between the gate 3 and the source, suppressing the turn-on of the parasitic triode, such that the leakage is reduced.

In some embodiments, the gate insulating layer 4 is disposed around the drain region 21, the channel region 22, and the source region 23.

In the embodiments, the gate insulating layer 4 is disposed around the drain region 21, the source region 23, and the channel region 22 at the same time, and the gate insulating layer 4 disposed around the drain region 21 has a smaller dielectric constant than the gate insulating layer 4 disposed around the source region 23, suppressing the turn-on of the parasitic triode, such that the leakage is reduced.

In some embodiments, the gate 3 includes a first gate 31 and a second gate 32 laminated together, the second gate 32 proximal to the source region 23 has a greater work function than the first gate 31 proximal to the drain region 21, and a work function difference between the second gate 32 and the first gate 31 is no less than 0.1 electron volt and no more than 0.5 electron volt.

In the embodiments, the second gate 32 proximal to the source region 23 has a greater work function than the first gate 31 proximal to the drain region 21, and the work function difference between the second gate 32 and the first gate 31 is within the range described above, which facilitates the electric field distribution in the channel region 22 to be more uniform, increases the on-state current, and decreases the off-state current, thereby improving the on-off ratio of the memory.

In some embodiments, a material of the first gate 31 includes undoped polysilicon, and a material of the second gate 32 includes polysilicon doped with P-type dopant elements.

In the embodiments, the first gate 31 is made of undoped polysilicon, and the second gate 32 is made of heavily doped P-type polysilicon, such that the second gate 32 has a greater work function than the first gate 31.

In some embodiments, dopant ions of the source region 23, dopant ions of the drain region 21, and dopant ions of the channel region 22 are of the same polarity.

In the embodiments, the dopant ions of the source region 23, the dopant ions of the drain region 21, and the dopant ions of the channel region 22 are of the same polarity, i.e., the vertical transistor of the present disclosure is a junction-less transistor, such that the leakage is reduced. The doping concentrations of the dopant ions of the source region 23, the dopant ions of the drain region 21, and the dopant ions of the channel region 22 are the same or different. The doping concentrations of the dopant ions of the source region 23, the dopant ions of the drain region 21, and the dopant ions of the channel region 22 are selected according to actual needs.

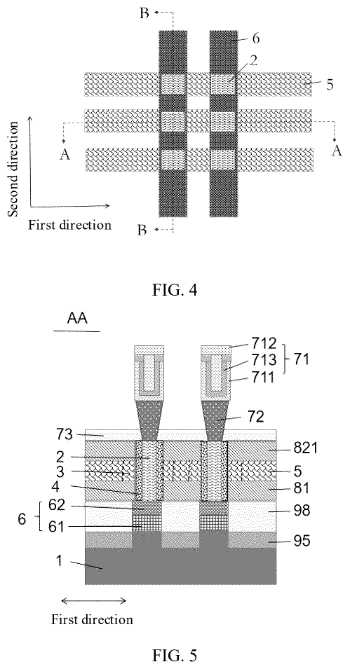

Based on the same inventive concept, the embodiments of the present disclosure provide a memory. The memory has a structure schematically shown in FIG. 4 to FIG. 10, and includes a plurality of wordlines 5, and memory cells arranged in an array as defined in the above embodiments.

Each of the wordlines 5 is electrically connected to the gates 3 of the memory cells arranged in the same row in a first direction, and the first direction is parallel to the substrate 1.

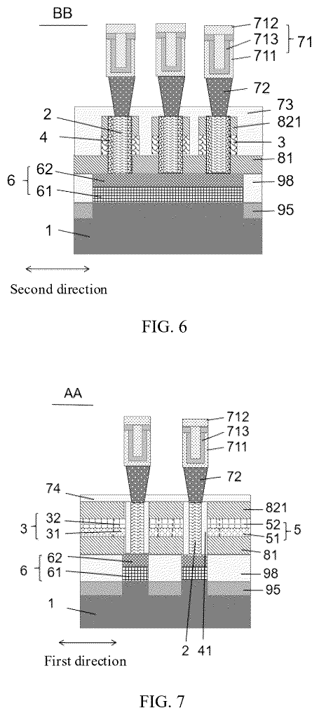

In the embodiments, FIG. 4 is a schematic top view of a memory according to some embodiments of the present disclosure. As the vertical transistors have three structures, the memories constituted by the vertical transistors have three structures as well. FIG. 5 and FIG. 6 are schematic cross-sectional views of the first memory in the first direction and in the second direction, respectively, according to some embodiments of the present disclosure. In FIG. 5 and FIG. 6, the gate 3 has a consistent work function, while the gate insulating layer 4 has a gradient dielectric constant value. Specifically, the gate insulating layer 4 proximal to the source region 23 has a greater dielectric constant than the gate insulating layer 4 proximal to the drain region 21. With a great dielectric constant of the gate insulating layer 4 proximal to the source region 23, the coupling between the gate 3 and the source can be enhanced, which is conducive to increasing the band barrier height of the source region 23 and the channel region 22. With a small dielectric constant of the gate insulating layer 4 proximal to the drain region 21, the electric field between the drain region 21 and the channel region 22 can be reduced, which is conducive to increasing the band barrier height of the drain region 21 and the channel region 22. Therefore, the gate insulating layer 4 having the gradient dielectric constant value suppresses the turn-on of the parasitic triode, thereby reducing the leakage.

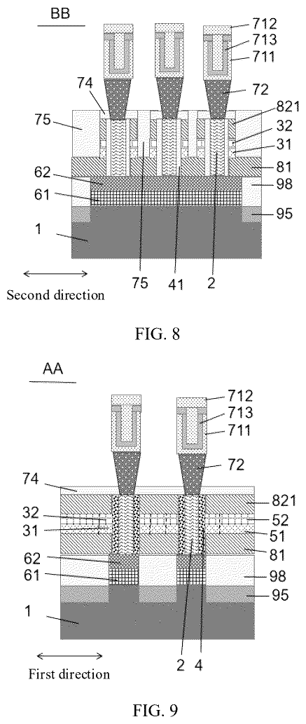

FIG. 7 and FIG. 8 are schematic cross-sectional views of the second memory in the first direction and in the second direction, respectively, according to some embodiments of the present disclosure. In FIG. 7 and FIG. 8, the gate insulating layer 41 has a constant dielectric constant value, while the gate 3 has different work functions. Specifically, the gate 3 proximal to the source region 23 has a greater work function than the gate 3 proximal to the drain region 21. With a great work function of the gate 3 proximal to the source region 23 and a small work function of the gate 3 proximal to the drain region 21, the electric field distribution in the channel region 22 becomes more uniform, such that the on-state current is increased, and meanwhile, the transverse band-band tunneling width is increased, which is conducive to reducing the off-state leakage current, thereby improving the on-off ratio of the memory.

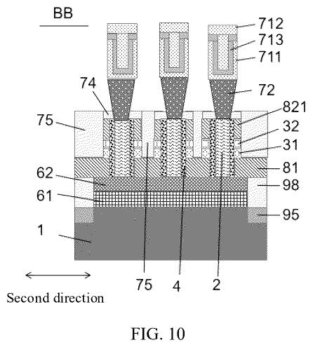

FIG. 9 and FIG. 10 are schematic cross-sectional views of the third memory in the first direction and in the second direction, respectively, according to some embodiments of the present disclosure. In FIG. 9 and FIG. 10, the gate insulating layer 4 has a gradient dielectric constant value, while the gate 3 has different work functions. The gate insulating layer 4 having the gradient dielectric constant value suppresses the turn-on of the parasitic triode, thereby reducing the leakage. The gate 3 having different work functions enables the electric field distribution in the channel region 22 to be more uniform, such that the on-state current is increased, and meanwhile, the transverse band-band tunneling width is increased, which is conducive to reducing the off-state leakage current, thereby improving the on-off ratio of the memory.

It should be noted that in the embodiments, the gates 3 and the wordlines 5 are disposed sequentially around the channel regions 22 of the semiconductor pillars 2. The dashed lines in FIG. 5, FIG. 7, and FIG. 9 do not exist in an actual product, but are only for illustrating the positional relationship between the gates 3 and the wordlines 5.

In some embodiments, each of the wordlines 5 includes a first wordline 51 and a second wordline 52 laminated together, the first wordline 51 is electrically connected to the first gate of the memory cell, the second wordline 52 is electrically connected to the second gate of the memory cell, the second wordline 52 is disposed proximal to the source region 23, and the first wordline 51 is disposed proximal to the drain region 21.

As shown in FIG. 7 to FIG. 10, each of the wordlines 5 includes the first wordline 51 and the second wordline 52 laminated together, the second wordline 52 disposed proximal to the source region 23 is electrically connected to the second gate 32, and the first wordline 51 disposed proximal to the drain region 21 is electrically connected to the first gate 31, such that the second wordline 52 has a greater work function than the first wordline 51.

In some embodiments and referring to FIG. 4 to FIG. 10, the memory further includes a plurality of bitlines 6 extending in the second direction, and each of the bitlines 6 is disposed at a side proximal to the substrate 1 of the semiconductor pillars 2 of the memory cells arranged in the same column in the second direction, and the second direction is parallel to the substrate 1 and has a designed angle with respect to the first direction.

In the embodiments, each of the bitlines 6 is electrically connected to the semiconductor pillars 2 of the memory cells arranged in the same column in the second direction.

It should be noted that the first direction has a designed angle with respect to the second direction, and the designed angle is 45°, 60°, 90°, 120°, 145°, and the like, which may be designed as needed. In the embodiments, the first direction is perpendicular to the second direction, and the designed angle is 90°.

In some embodiments, each of the bitlines 6 includes a first bitline 61 and a second bitline 62, the second bitline 62 is disposed at a side of the first bitline 61 distal to the substrate 1, a material of the first bitline 61 includes a metalized semiconductor, and a material of the second bitline 62 includes a doped semiconductor.

In the embodiments, the second bitline 62 is electrically connected to the semiconductor pillar 2, and the semiconductor pillar 2 is epitaxially formed at a side of the second bitline 62 distal to the substrate 1. The metalized semiconductor includes non-metal silicide. The second bitline 62 forms an ohmic contact with the drain region 21 of the semiconductor pillar 2, such that the contact resistance between the second bitline 62 and the drain region 21 is reduced. The first bitline 61 includes metal silicide, which reduces the resistance of the first bitline 61 itself.

In some embodiments, the memory further includes a capacitor structure 71, and the capacitor structure 71 is electrically connected to the semiconductor pillar 2 through a metal plug 72.

In some embodiments, the capacitor structure 71 includes a first electrode 711, a dielectric layer 713, and a second electrode 712, which are disposed sequentially distal to the semiconductor pillar 2.

Based on the same inventive concept, the embodiments of the present disclosure provide an electronic device. The electronic device includes the memory as defined in the above embodiments.

In the embodiments, as the electronic device adopts any one of the memories as defined in the foregoing embodiments, reference is made to the foregoing embodiments for the principles and technical effects, which are not repeated herein.

In some embodiments, the electronic device includes a smart phone, a computer, a tablet, artificial intelligence, a wearable device, or a smart mobile terminal.

It should be noted that the electronic device is not limited to those described above, and a person skilled in the art may provide, in various devices, any one of the memories as defined in the above embodiments of the present disclosure according to practical application needs, so as to obtain the electronic device as defined in the embodiments of the present disclosure.

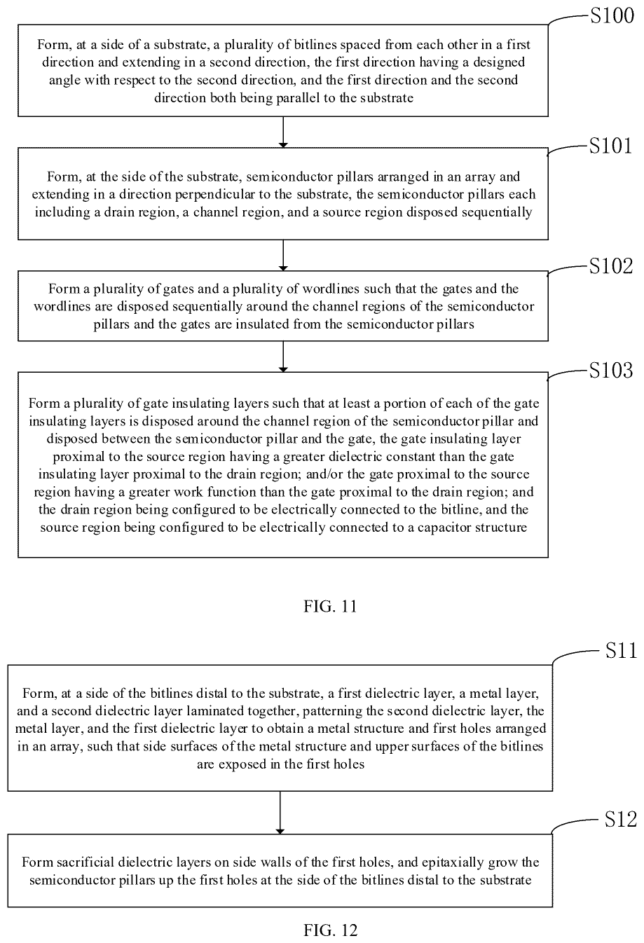

Based on the same inventive concept, the embodiments of the present disclosure provide a method for manufacturing a memory. The method for manufacturing a memory is illustrated in a flowchart shown in FIG. 11 and the method includes the following steps S101 to S103:
In S101, semiconductor pillars 2 arranged in an array and extending in a direction perpendicular to a substrate 1 are formed at a side of the substrate 1, and each of the semiconductor pillars 2 includes a drain region 21, a channel region 22, and a source region 23 disposed sequentially.

In some embodiments, the step S101 includes the following steps S11 to S12 as illustrated in a flowchart shown in FIG. 12.

In S11, a first dielectric layer 81, a metal layer 83, and a second dielectric layer 82 laminated together are formed at a side of the bitlines 6 distal to the substrate 1, the second dielectric layer 82, the metal layer 83, and the first dielectric layer 81 are patterned to obtain a metal structure 84 and first holes 85 arranged in an array, such that side surfaces of the metal structure 84 and upper surfaces of the bitlines 6 are exposed in the first holes 85.

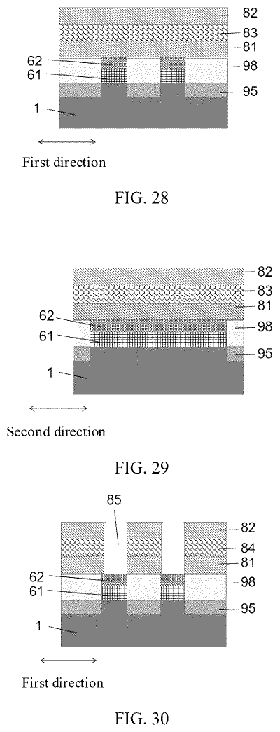

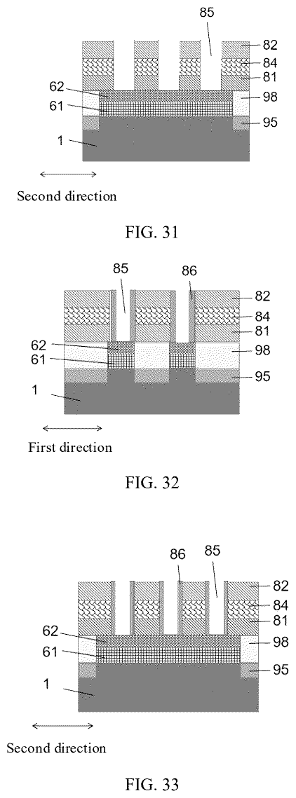

In the embodiments, FIG. 28 and FIG. 29 are schematic cross-sectional views in the first direction and in the second direction, respectively, after the first dielectric layer 81, the metal layer 83, and the second dielectric layer 82 laminated together are formed at the side of the bitlines 6 distal to the substrate 1. FIG. 30 and FIG. 31 are schematic cross-sectional views in the first direction and in the second direction, respectively, after the second dielectric layer 82, the metal layer 83, and the first dielectric layer 81 are patterned to obtain the first holes 85 arranged in the array and the metal structure 84, such that the side surfaces of the metal structure 84 and the upper surfaces of the bitlines 6 are exposed in the first holes 85.

In the embodiments, a material of the first dielectric layer 81 and a material of the second dielectric layer 82 both are silicon dioxide, and a material of the metal layer 83 is titanium nitride.

In S12, sacrificial dielectric layers 86 are formed on side walls of the first holes 85, and the semiconductor pillars 2 are epitaxially grown up the first holes 85 at the side of the bitlines 6 distal to the substrate 1.

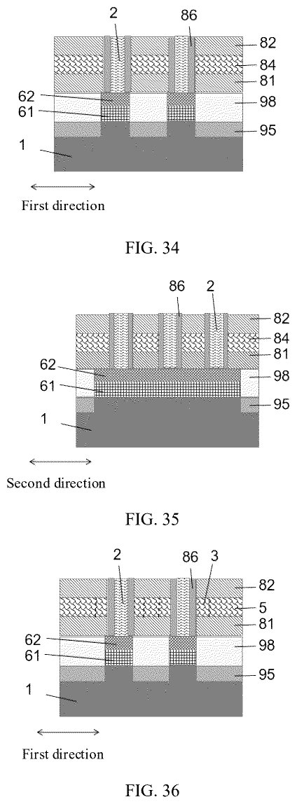

In the embodiments, FIG. 32 and FIG. 33 are schematic cross-sectional views in the first direction and in the second direction, respectively, after the sacrificial dielectric layers 86 are formed on the side walls of the first holes 85. FIG. 34 and FIG. 35 are schematic cross-sectional views in the first direction and in the second direction, respectively, after the semiconductor pillars 2 are epitaxially grown up the first holes 85 at the side of the bitlines 6 distal to the substrate 1;

In the embodiments, the upper surfaces of the second bitlines 62 are exposed after the sacrificial dielectric layers 86 are formed on the side walls of the first hole 85, so as to epitaxially form the semiconductor pillars 2 on the upper surfaces of the second bitlines 62.

Specifically, a material of the sacrificial dielectric layers 86 is silicon nitride; and the thickness of the sacrificial dielectric layers 86 is no less than 4 nm and no more than 6 nm. In the embodiments, the thickness of the sacrificial dielectric layers 86 is 5 nm.

By epitaxially forming the semiconductor pillars 2 directly on the surfaces of the bitlines 6, the drain region 21, the channel region 22, and the source region 23 of each of the semiconductor pillars 2 are of the same polarity, for example, all being n-type silicon. The semiconductor pillars 2 have a doping concentration of no less than 5×10¹⁸ cm⁻³ (per cubic centimeter) and no more than 1×10¹⁹ cm⁻³.

In S102, a plurality of gates 3 and a plurality of wordlines 5 are formed such that the gates 3 and the wordlines 5 are disposed sequentially around the channel regions 22 of the semiconductor pillars 2 and the gates 3 are insulated from the semiconductor pillars 2.

In some embodiments, the step S102 includes: patterning the metal structure 84 to obtain the gates 3 and the wordlines 5 disposed sequentially around the sacrificial dielectric layers 86.

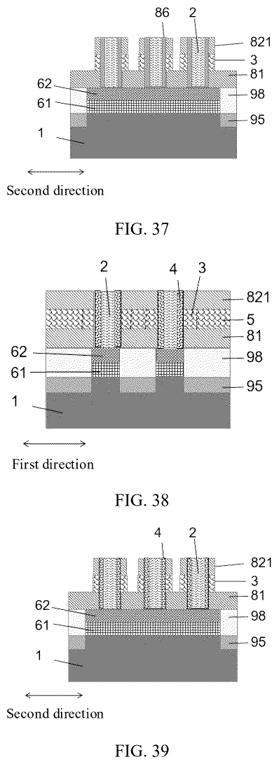

In the embodiments, FIG. 36 and FIG. 37 are schematic cross-sectional views in the first direction and in the second direction, respectively, after the metal structure 84 is patterned to obtain the gates 3 and the wordlines 5 disposed sequentially around the sacrificial dielectric layers 86.

In the embodiments, each of the wordlines 5 extends in the first direction and is electrically connected to the gates 3 in the same column in the first direction.

While the metal structure 84 is patterned, the second dielectric layer 82 is patterned as well, resulting in a second dielectric structure 821.

In S103, a plurality of gate insulating layers 4 are formed such that at least a portion of each of the gate insulating layers 4 is disposed around the channel region 22 of the semiconductor pillar 2 and disposed between the semiconductor pillar 2 and the gate 3, the gate insulating layer 4 proximal to the source region 23 has a greater dielectric constant than the gate insulating layer 4 proximal to the drain region 21; and/or the gate 3 proximal to the source region 23 has a greater work function than the gate 3 proximal to the drain region 21; and the drain region 21 is configured to be electrically connected to the bitline 6, and the source region 23 is configured to be electrically connected to a capacitor structure 71.

In some embodiments, the step S103 includes: removing the sacrificial dielectric layer 86 and forming the gate insulating layer 4 between the semiconductor pillar 2 and the gate 3 such that at least a portion of the gate insulating layer 4 is disposed around the channel region 22 of the semiconductor pillar 2 and disposed between the semiconductor pillar 2 and the gate 3.

In the embodiments, FIG. 38 and FIG. 39 are schematic cross-sectional views in the first direction and in the second direction, respectively, after the sacrificial dielectric layer 86 is removed and the gate insulating layer 4 is formed between the semiconductor pillar 2 and the gate 3.

In some embodiments, removing the sacrificial dielectric layer 86 and forming the gate insulating layer 4 between the semiconductor pillar 2 and the gate 3 includes: controlling the dielectric constant of the gate insulating layer 4 based on an atomic layer deposition (ALD) doping process, such that the gate insulating layer 4 proximal to the source region 23 has a greater dielectric constant than the gate insulating layer 4 proximal to the drain region 21 of the semiconductor pillar 2.

In the embodiments and referring to FIG. 38 and FIG. 39, the gate insulating layer 4 having a gradient dielectric constant is formed, which suppresses the turn-on of the parasitic triode, such that the leakage is reduced.

In some embodiments, forming, at the side of the bitlines 6 distal to the substrate 1, the first dielectric layer 81, the metal layer 83, and the second dielectric layer 82 laminated together in the step S11 includes:
The first dielectric layer 81, a first metal layer 831, a second metal layer 832, and the second dielectric layer 82 laminated together are formed at the side of the bitlines 6 distal to the substrate 1, such that the second metal layer 832 has a greater work function than the first metal layer 831, and the metal layer 83 includes the first metal layer 831 and the second metal layer 832 laminated together.

In the embodiments, FIG. 44 and FIG. 45 are schematic cross-sectional views in the first direction and in the second direction, respectively, after the first dielectric layer 81, the first metal layer 831, the second metal layer 832, and the second dielectric layer 82 laminated together are formed at the side of the bitlines 6 distal to the substrate 1.

In the embodiments, the formed second metal layer 832 has a greater work function than the first metal layer 831, such that the electric field distribution in the channel region 22 is more uniform, thus improving the on-off ratio of the device.

In some embodiments, after the first dielectric layer 81, the first metal layer 831, the second metal layer 832, and the second dielectric layer 82 laminated together are formed at the side of the bitlines 6 distal to the substrate 1, the method for manufacturing the memory further includes:
The first dielectric layer 81, the first metal layer 831, the second metal layer 832, and the second dielectric layer 82 are patterned to obtain a first metal structure 8311, a second metal structure 8321, and the first holes 85 arranged in the array, such that side surfaces of the first metal structure 8311 and the second metal structure 8321, and the upper surfaces of the bitlines 6 are exposed in the first holes 85.

In the embodiments, FIG. 46 and FIG. 47 are schematic cross-sectional views in the first direction and in the second direction, respectively, after the first dielectric layer 81, the first metal layer 831, the second metal layer 832, and the second dielectric layer 82 are patterned to obtain the first metal structure 8311, the second metal structure 8321, and the first holes 85 arranged in the array, such that the side surfaces of the first metal structure 8311 and the second metal structure 8321, and the upper surfaces of the bitlines 6 are exposed in the first holes 85.

The sacrificial dielectric layers 86 are formed on the side walls of the first holes 85.

In the embodiments, FIG. 48 and FIG. 49 are schematic cross-sectional views in the first direction and in the second direction, respectively, after the sacrificial dielectric layers 86 are formed on the side walls of the first holes 85.

The semiconductor pillars 2 are epitaxially grown up the first holes 85 at the side of the bitlines 6 distal to the substrate 1.

In the embodiments, FIG. 50 and FIG. 51 are schematic cross-sectional views in the first direction and in the second direction, respectively, after the semiconductor pillars 2 are epitaxially grown up the first holes 85 at the side of the bitlines 6 distal to the substrate 1.

The first metal structure 8311 and the second metal structure 8321 are patterned to form the plurality of gates 3 and the plurality of wordlines 5 such that the gates 3 and the wordlines 5 are disposed sequentially around the channel regions 22 of the semiconductor pillars 2 and the gates 3 are insulated from the semiconductor pillars 2.

In the embodiments, FIG. 52 and FIG. 53 are schematic cross-sectional views in the first direction and in the second direction, respectively, after the first metal structure 8311 and the second metal structure 8321 are patterned to obtain the gates 3 and the wordlines 5 disposed sequentially around the sacrificial dielectric layers 86.

The sacrificial dielectric layers 86 are removed and the gate insulating layers 41 are formed between the semiconductor pillars 2 and the gates 3 such that the gate insulating layers 41 have a consistent dielectric constant.

In the embodiments, FIG. 54 and FIG. 55 are schematic cross-sectional views in the first direction and in the second direction, respectively, after the sacrificial dielectric layers 86 are removed and the gate insulating layers 41 are formed between the semiconductor pillars 2 and the gates 3 such that the gate insulating layers 41 have a consistent dielectric constant.

Second isolation layers 74 are formed on surfaces of the semiconductor pillars 2 in the same column in the second direction, and third isolation layers 75 are formed between the semiconductor pillars 2.

In the embodiments, FIG. 56 and FIG. 57 are schematic cross-sectional views in the first direction and in the second direction, respectively, after the second isolation layers 74 are formed on the surfaces of the semiconductor pillars 2 in the same column in the second direction. FIG. 58 and FIG. 59 are schematic cross-sectional views in the first direction and in the second direction, respectively, after the third isolation layers 75 are formed between the semiconductor pillars 2.

In some embodiments, after the step S103, the method for manufacturing a memory further includes:
A first isolation layer 73 is formed at a side of the semiconductor pillars 2 distal to the substrate 1, the first isolation layer 73 over the semiconductor pillars 2 is patterned to obtain metal via holes, and a metal plug 72 is disposed in each of the metal via holes.

A capacitor structure 71 is formed over the vertical transistor such that the capacitor structure 71 is electrically connected to the semiconductor pillar 2 through the metal plug 72.

In the embodiments, the capacitor structure 71 includes a first electrode 711, a dielectric layer 713, and a second electrode 712, which are disposed sequentially distal to the vertical transistor.

Each of the first electrode 711 and the second electrode 712 includes at least one of titanium nitride and tantalum nitride; and the dielectric layer 713 includes zirconium oxide, aluminum oxide, and zirconium oxide laminated together.

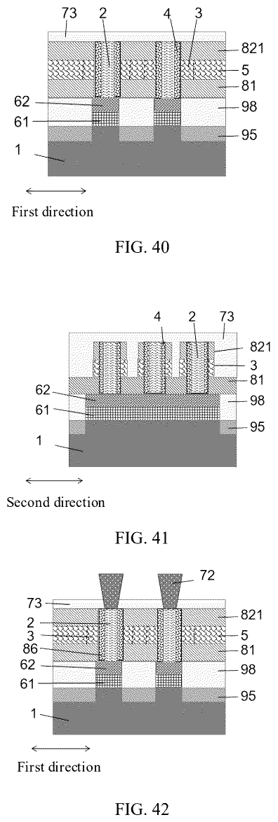

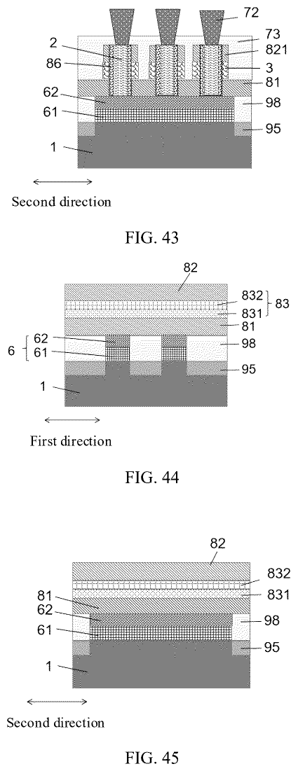

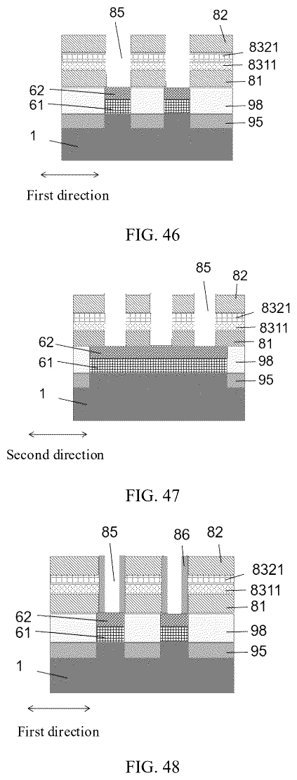

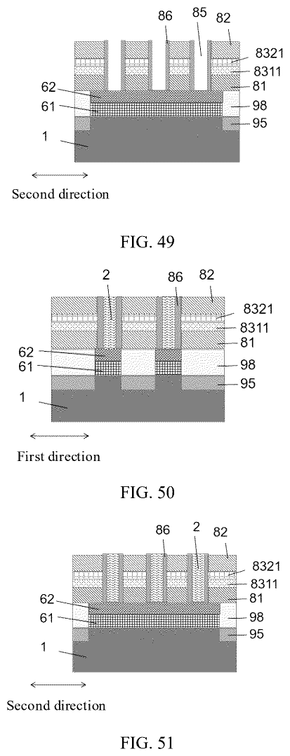

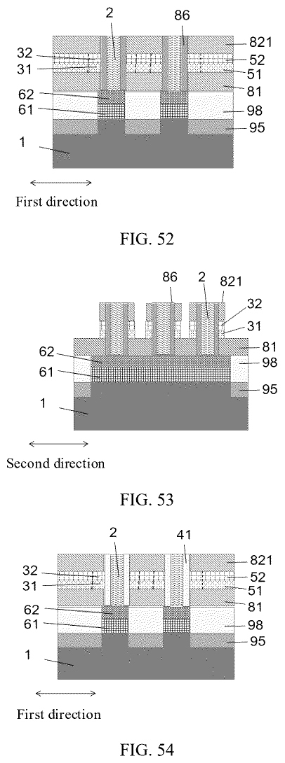

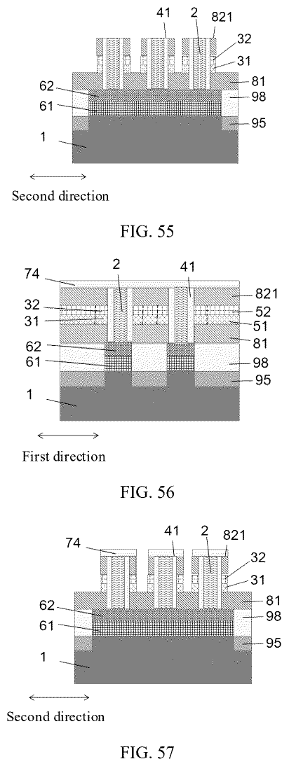

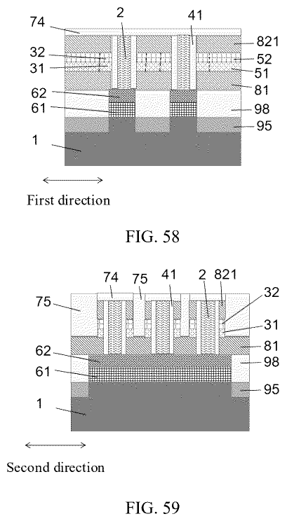

FIG. 40 and FIG. 41 are schematic cross-sectional views in the first direction and in the second direction, respectively, after the first isolation layer 73 is formed at the side of the semiconductor pillars 2 distal to the substrate 1. FIG. 42 and FIG. 43 are schematic cross-sectional views in the first direction and in the second direction, respectively, after the first isolation layer 73 over the semiconductor pillars 2 is patterned to obtain the metal via holes and the metal plug 72 is disposed in each of the metal via holes.

In some embodiments, prior to the step S101, the following step S100 is further included: forming, at the side of the substrate 1, a plurality of bitlines 6 spaced from each other in the first direction and extending in the second direction, the first direction having a designed angle with respect to the second direction, and the first direction and the second direction both being parallel to the substrate 1.

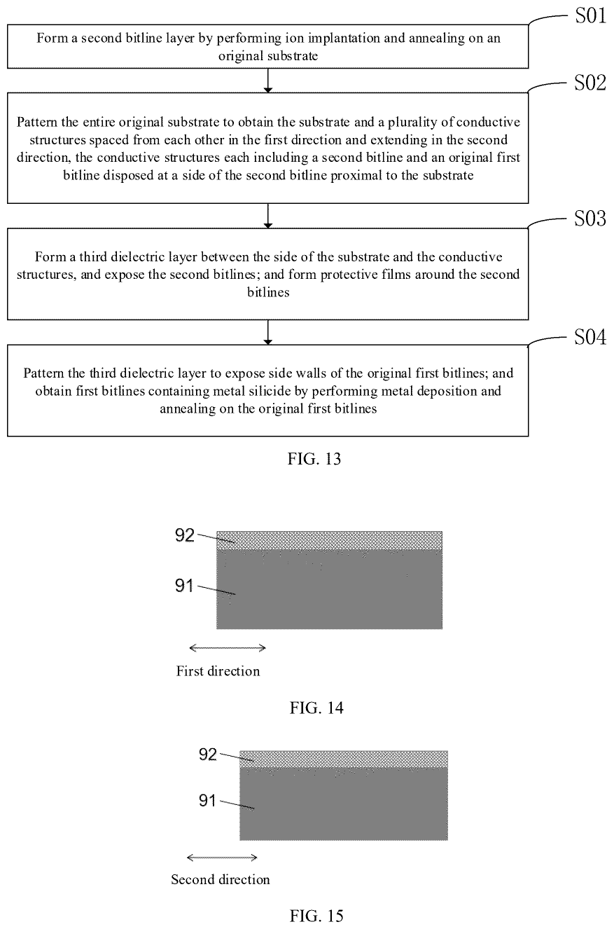

In some embodiments, the step S100 further includes the following steps S01 to S04 as illustrated in a flowchart shown in FIG. 13.

In S01, a second bitline layer 92 is formed by performing ion implantation and annealing on an original substrate 91.

In the embodiments, FIG. 14 and FIG. 15 are schematic cross-sectional views in the first direction and in the second direction, respectively, after the second bitline layer 92 is formed by performing ion implantation and annealing on the original substrate 91.

Specifically, ion implantation is performed at a concentration that is no less than 1×20 cm⁻³ and no more than 1×20 cm⁻³, so as to form an ohmic contact with the drain of the semiconductor pillar 2 to be subsequently formed, such that the contact resistance is reduced.

In S02, the entire original substrate 91 is patterned to obtain the substrate 1 and a plurality of conductive structures 93 spaced from each other in the first direction and extending in the second direction, and each of the conductive structures 93 includes a second bitline 62 and an original first bitline 94 disposed at a side of the second bitline 62 proximal to the substrate 1.

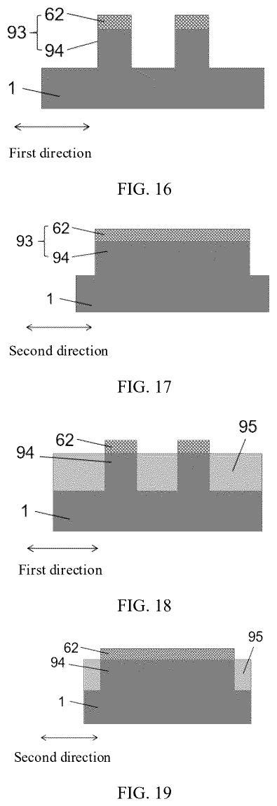

In the embodiments, FIG. 16 and FIG. 17 are schematic cross-sectional views in the first direction and in the second direction, respectively, obtained after the entire original substrate 91 and the second bitline layer 92 are patterned to obtain the substrate 1 and the plurality of conductive structures 93 spaced from each other in the first direction and extending in the second direction.

Specifically, the patterning includes coating photoresist at a side of the original substrate 91, and performing processes, such as exposure, development, and etching, on the photoresist with a mask. The resulting conductive structures 93 each have the second bitline 62 and the original first bitline 94 exposed.

In S03, a third dielectric layer 95 is formed between the side of the substrate 1 and the conductive structures 93, and the second bitlines 62 are exposed, and protective films 96 are formed around the second bitlines 62.

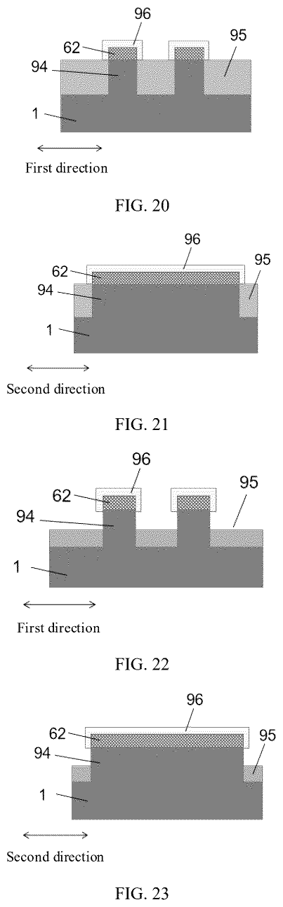

In the embodiments, FIG. 18 and FIG. 19 are schematic cross-sectional views in the first direction and in the second direction, respectively, after the third dielectric layer 95 is formed between the side of the substrate 1 and the conductive structures 93 and the second bitlines 62 are exposed. FIG. 20 and FIG. 21 are schematic cross-sectional views in the first direction and in the second direction, respectively, after the protective films 96 are formed around the second bitlines 62.

In some embodiments, a material of the protective films 96 is silicon nitride doped with oxygen. Specifically, the silicon nitride is formed through doping nitrogen under thermal oxygen conditions.

In some embodiments, a material of the third dielectric layer 95 is silicon nitride.

In some embodiments, the step S03 includes: depositing an original third dielectric layer 95 between the side of the substrate 1 and the conductive structures 93, and etching back the original third dielectric layer 95 to expose the second bitlines 62, such that the third dielectric layer 95 is obtained.

In S04, the third dielectric layer 95 is patterned to expose side walls of the original first bitlines 94, and first bitlines 61 containing metal silicide are obtained by performing metal deposition and annealing on the original first bitlines 94.

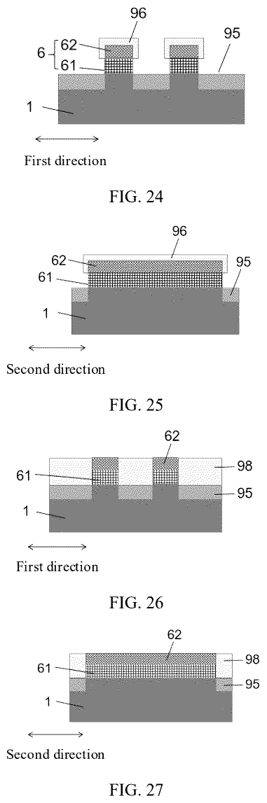

In the embodiments, FIG. 22 and FIG. 23 are schematic cross-sectional views in the first direction and in the second direction, respectively, after the third dielectric layer 95 is patterned to expose the side walls of the original first bitlines 94. FIG. 24 and FIG. 25 are schematic cross-sectional views in the first direction and in the second direction, respectively, after the first bitlines 61 containing metal silicide are obtained by performing metal deposition and annealing on the original first bitlines 94.

Each of the first bitlines 61 contains metal silicide, which reduces the resistance of the first bitline 61 itself.

In some embodiments, after the step S04 and prior to the step S11, the following step is further included:
The protective films 96 are removed, a fourth dielectric layer 98 is formed over the third dielectric layer 95 and upper surfaces of the second bitlines 62 are exposed.

In the embodiments, FIG. 26 and FIG. 27 are schematic cross-sectional views in the first direction and in the second direction, respectively, after the fourth dielectric layer 98 is formed over the third dielectric layer 95 and the upper surfaces of the second bitlines 62 are exposed.

The semiconductor pillars 2 are epitaxially formed on the exposed upper surfaces of the second bitlines 62.

With the embodiments of the present disclosure, at least the following beneficial effects can be achieved:
1. The gate insulating layer as defined in the embodiments of the present disclosure has a gradient dielectric constant value, and the gate has different work functions. The gate insulating layer having the gradient dielectric constant value suppresses the turn-on of a parasitic triode, thereby reducing the leakage. The gate having different work functions enables the electric field distribution in the channel region to be more uniform, which increases an on-state current, and meanwhile, the transverse band-band tunneling width is increased, which reduces an off-state leakage current, thereby improving the on-off ratio of the memory.

Those skilled in the art will understand that various steps, measures, and schemes in the operations, methods, and procedures discussed in the present disclosure may be alternated, modified, combined, or deleted. Further, other steps, measures, and schemes in the operations, methods, and procedures discussed in the present disclosure may also be alternated, modified, rearranged, split, combined, or deleted. Further, steps, measures, and schemes in the operations, methods, and procedures disclosed in the prior art and the present disclosure may also be alternated, modified, rearranged, split, combined, or deleted.

In the descriptions of the present disclosure, directional or positional relationships indicated by the words, such as “central”, “upper”, “lower”, “front”, “rear”, “left”, “right”, “vertical”, “horizontal”, “top”, “bottom”, “inner”, “outer”, based on exemplary directional or positional relationships shown in the accompanying drawings, are merely for convenience of description or a simplified description of the embodiments of the present disclosure, and are not intended to indicate or imply that the referred apparatus or component must have a particular orientation or be constructed and operated in a particular orientation, and thus, are not to be construed as limiting the present disclosure.

The terms “first” and “second” are merely used for descriptive purposes and are not to be construed as indicating or implying the relative importance or as implicitly designating the number of indicated technical features. Thus, features defined as “first” and “second” explicitly or implicitly include one or more of the features. In the descriptions of the present disclosure, “a plurality” means two or more, unless otherwise specified.

In the descriptions of the present disclosure, it should be noted that, unless otherwise specified or defined explicitly, the terms “mount”, “attach”, and “connect” are to be interpreted broadly, for example, as a fixed connection, a detachable connection, or an integral connection, which may be a direct attachment, an indirect attachment through an intermediate medium, or an internal communication between two elements. For those of ordinary skill in the art, the specific meaning of the above terms in the present disclosure may be understood according to the specific condition.

In the descriptions of the specification, the specific features, structures, materials, or characteristics may be combined in any suitable manner in any one or more embodiments or examples.

It should be understood that, although the steps in the flowcharts of the accompanying drawings are shown in order as indicated by the arrows, the steps are not necessarily performed in order as indicated by the arrows. In some implementations of the embodiments of the present disclosure, the steps in the flowcharts may be performed in another order as needed, unless explicitly stated otherwise herein. Moreover, some or all of the steps in the flowcharts may include a plurality of sub-steps or a plurality of stages based on an actual implementation. Some or all of the sub-steps or stages may be performed at the same time, or may be performed at different times where the order of the sub-steps or stages may be flexibly configured as needed, which is not limited in the embodiments of the present disclosure.

The foregoing is merely a part of the embodiments of the present disclosure, and it should be noted that, for those skilled in the art, other similar implementations based on the technical idea of the present disclosure may be adopted without departing from the technical concept of the present disclosure and are covered by the embodiments of the present disclosure.

1. A memory cell, comprising:
a vertical transistor comprising:
a semiconductor pillar extending in a direction perpendicular to a substrate and comprising a drain region, a channel region, and a source region disposed sequentially; and
a gate insulating layer and a gate, the gate and at least a portion of the gate insulating layer being disposed sequentially around the channel region of the semiconductor pillar,
wherein the vertical transistor includes at least one of the gate insulating layer proximal to the source region having a greater dielectric constant than the gate insulating layer proximal to the drain region or the gate proximal to the source region having a greater work function than the gate proximal to the drain region, and
wherein the drain region is configured to be electrically connected to a bitline, and the source region is configured to be electrically connected to a capacitor structure.

2. The memory cell according to claim 1, wherein the gate insulating layer is disposed around the drain region, the channel region, and the source region.

3. The memory cell according to claim 1, wherein the gate comprises a first gate proximal to the drain region and a second gate proximal to the source region that are laminated, the second gate having a greater work function than the first gate and a work function difference between the second gate and the first gate being no less than 0.1 electron volt and no more than 0.5 electron volt.

4. The memory cell according to claim 3, wherein a material of the first gate comprises undoped polysilicon, and a material of the second gate comprises polysilicon doped with P-type dopant elements.

5. The memory cell according to claim 1, wherein dopant ions in the source region, dopant ions in the drain region, and dopant ions in the channel region are of a same polarity.

6. A memory, comprising:
a plurality of wordlines, and memory cells disposed in an array, each of the memory cells comprising a vertical transistor, wherein the vertical transistor comprises:
a semiconductor pillar extending in a direction perpendicular to a substrate and comprising a drain region, a channel region, and a source region disposed sequentially; and
a gate insulating layer and a gate, the gate and at least a portion of the gate insulating layer being disposed sequentially around the channel region of the semiconductor pillar,
wherein the vertical transistor includes at least one of the gate insulating layer proximal to the source region having a greater dielectric constant than the gate insulating layer proximal to the drain region or the gate proximal to the source region having a greater work function than the gate proximal to the drain region,
wherein the drain region is configured to be electrically connected to a bitline, and the source region is configured to be electrically connected to a capacitor structure_and
wherein each of the wordlines is electrically connected to the gates of the memory cells arranged in a same row in a first direction, the first direction being parallel to the substrate.

7. The memory according to claim 6, wherein the gate insulating layer is disposed around the drain region, the channel region, and the source region.

8. The memory according to claim 6, wherein the gate comprises a first gate and a second gate that are laminated, each of the wordlines comprises a first wordline and a second wordline that are laminated, the first wordline is electrically connected to the first gate, the second wordline is electrically connected to the second gate, the second wordline is proximal to the source region, the first wordline is proximal to the drain region, and the second wordline has a greater work function than the first wordline.

9. The memory according to claim 8, wherein a material of the first wordline comprises undoped polysilicon, and a material of the second wordline comprises polysilicon doped with P-type dopant elements.

10. The memory according to claim 6, further comprising a plurality of bitlines extending in a second direction, wherein each of the bitlines is disposed at a side proximal to the substrate of the semiconductor pillars arranged in a same column in the second direction, the second direction being parallel to the substrate and having a designed angle with respect to the first direction.

11. The memory according to claim 10, wherein each of the bitlines comprises a first bitline and a second bitline, the second bitline is disposed at a side distal to the substrate of the first bitline, a material of the first bitline comprises a metalized semiconductor, and a material of the second bitline comprises a doped semiconductor.

12. The memory according to claim 6, wherein dopant ions of the source region, dopant ions of the drain region, and dopant ions of the channel region are of a same polarity.

13. (canceled)

14. A method for manufacturing a memory, comprising:
forming, at a side of a substrate, semiconductor pillars arranged in an array and extending in a direction perpendicular to the substrate, each of the semiconductor pillars comprising a drain region, a channel region, and a source region disposed sequentially;
forming a plurality of gates and a plurality of wordlines, such that the gates and the wordlines are disposed sequentially around the channel regions of the semiconductor pillars and the gates are insulated from the semiconductor pillars; and
forming a plurality of gate insulating layers, such that at least a portion of each of the gate insulating layers is disposed around the channel region of the semiconductor pillar and disposed between the semiconductor pillar and the gate,
wherein the vertical transistor includes at least one of the gate insulating layer proximal to the source region having a greater dielectric constant than the gate insulating layer proximal to the drain region or the gate proximal to the source region having a greater work function than the gate proximal to the drain region, and
wherein the drain region is configured to be electrically connected to a bitline, and the source region is configured to be electrically connected to a capacitor structure.

15. The method according to claim 14, wherein prior to forming, at the side of the substrate, the semiconductor pillars arranged in the array and extending in the direction perpendicular to the substrate, the method further comprises:
forming, at the side of the substrate, a plurality of bitlines spaced from each other in a first direction and extending in a second direction, the first direction having a designed angle with respect to the second direction, and the first direction and the second direction both being parallel to the substrate; and
forming, at the side of the substrate, the semiconductor pillars arranged in the array and extending in the direction perpendicular to the substrate comprises:
forming, at a side of the bitlines distal to the substrate, a first dielectric layer, a metal layer, and a second dielectric layer stacked together, patterning the second dielectric layer, the metal layer, and the first dielectric layer to obtain a metal structure and first holes arranged in an array, such that side surfaces of the metal structure and upper surfaces of the bitlines are exposed in the first holes; and
forming sacrificial dielectric layers on side walls of the first holes, and epitaxially forming the semiconductor pillars up the first holes at the side of the bitlines distal to the substrate.

16. The method according to claim 15, wherein forming the plurality of gates and the plurality of wordlines such that the gates and the wordlines are disposed sequentially around the channel regions of the semiconductor pillars comprises:
patterning the metal structure to obtain the gates and the wordlines disposed sequentially around the sacrificial dielectric layers, wherein each of the wordlines is electrically connected to the gates arranged in a same row in the first direction.

17. (canceled)

18. The method according to claim 16, wherein each of the gates comprises a first gate and a second gate that are laminated, the second gate proximal to the source region has a greater work function than the first gate proximal to the drain region, and a work function difference between the second gate and the first gate is no less than 0.1 electron volt and no more than 0.5 electron volt, and wherein a material of the first gate comprises undoped polysilicon, and a material of the second gate comprises polysilicon doped with P-type dopant elements.

19. (canceled)

20. (canceled)

21. The method according to claim 15, wherein forming the plurality of gate insulating layers such that at least a portion of each of the gate insulating layers is disposed around the channel region of the semiconductor pillar and positioned between the semiconductor pillar and the gate comprises:
removing the sacrificial dielectric layer; and
forming the gate insulating layer between the semiconductor pillar and the gate, such that at least a portion of the gate insulating layer is disposed around the channel region of the semiconductor pillar and positioned between the semiconductor pillar and the gate.

22. The method according to claim 21, wherein removing the sacrificial dielectric layer and forming the gate insulating layer between the semiconductor pillar and the gate comprises:
controlling the dielectric constant of the gate insulating layer based on an atomic layer deposition (ALD) doping process, such that the gate insulating layer proximal to the source region of the semiconductor pillar has a greater dielectric constant than the gate insulating layer proximal to the drain region.

23. (canceled)

24. The method according to claim 15, wherein forming, at the side of the bitlines distal to the substrate, the first dielectric layer, the metal layer, and the second dielectric layer stacked together comprises:
forming, at the side of the bitlines distal to the substrate, the first dielectric layer, a first metal layer, a second metal layer, and the second dielectric layer that are laminated, such that the second metal layer has a greater work function than the first metal layer, the metal layer comprising the first metal layer and the second metal layer that are laminated.

25. The method according to claim 15, wherein forming, at the side of the substrate, the plurality of bitlines spaced from each other in the first direction and extending in the second direction comprises:
forming a second bitline layer by performing ion implantation and annealing on an original substrate;
patterning the entire original substrate to obtain the substrate and a plurality of conductive structures spaced from each other in the first direction and extending in the second direction, each of the conductive structures comprising a second bitline and an original first bitline disposed at a side of the second bitline proximal to the substrate;
forming a third dielectric layer between the side of the substrate and the conductive structures, and exposing the second bitlines;
forming protective films around the second bitlines;
patterning the third dielectric layer to expose side walls of the original first bitlines; and
obtaining first bitlines containing metal silicide by performing metal deposition and annealing on the original first bitlines.

26. (canceled)

27. (canceled)
